(19) United States
(12) Patent Application Publication
(10) Pub. No.: US 2010/0193132 A1
(43) Pub. Date: Aug. 5, 2010

(54) MULTI-WORKPIECE PROCESSING CHAMBER AND WORKPIECE PROCESSING SYSTEM INCLUDING THE SAME

(75) Inventors: Soon Im Wi, Gyeonggi-do (KR); Chang Woo Nam, Yongin-si (KR)

Correspondence Address: North Star Intellectual Property Law, PC, P.O. Box 34688, Washington, DC, 20043, US

(73) Assignee: NEW POWER PLASAMA CO., LTD., Suwon-si, Gyeonggi-do (KR)

(21) Appl. No.: 12/597,924

(22) PCT Filed: Apr. 2, 2009
(86) PCT No.: PCT/KR2009/001680

§ 371 Date: Mar. 25, 2010

(30) Foreign Application Priority Data
Jul. 23, 2008 (KR) 10-2008-0071939
Jul. 23, 2008 (KR) 10-2008-0071940
Jul. 23, 2008 (KR) 10-2008-0071941

(51) Int. Cl. C23F 1/08; C23C 16/00

(52) U.S. Cl. 156/345.51; 118/719

(57) ABSTRACT

A multi-workpiece processing chamber according to the present invention comprises a chamber housing which forms at least two internal processing spaces therein; at least one partition member which is provided in the chamber housing and partitions the chamber housing into at least two internal processing spaces; and the respective internal processing spaces being coupled with the partition member and having a symmetric shape to generate a processing reaction uniformly. The multi-workpiece processing chamber according to the present invention has internal processing spaces that have a symmetric shape by being coupled with a partition member. Thus, a processing reaction uniformly occurs across the internal processing areas and reproducibility and uniformity of a workpiece processing process may improve.

### TECHNICAL FIELD

Apparatuses and methods consistent with the present invention relate to a multi-workpiece chamber and a workpiece processing system including the same, and more particularly, to a multi-workpiece processing chamber which has a plurality of internal processing spaces and a workpiece processing system including the same.

### BACKGROUND ART

In recent years, workpiece processing systems which are used for manufacturing liquid crystal display (LCD) devices, plasma display panels (PDPs) and semiconductor devices have employed a cluster system to process a plurality of workpieces at a time. The cluster system refers to a multi-chamber type workpiece processing system which includes a transfer robot (or a handler) and a plurality of workpiece processing modules that is provided in the circumference of the transfer robot. Generally, the cluster system includes a transfer chamber and a transfer robot which is provided to rotate freely within the transfer chamber. In each side of the transfer chamber is mounted a workpiece processing chamber to perform a processing of workpieces. Such a cluster system may process a plurality of workpieces simultaneously or perform several processes consecutively to thereby raise the processing rate of workpieces. In another attempt to raise the processing rate of workpieces per hour, a plurality of workpieces is simultaneously processed in a multi-workpiece processing chamber.

U.S. Pat. No. 6,077,157 discloses a multi-workpiece processing chamber which processes a plurality of workpieces at a time. The multi-workpiece processing chamber has such a configuration that spaces are divided by a partition formed integrally in the chamber and each of the divided spaces includes a workpiece processing station therein. Thus, the two workpiece processing stations may process the workpieces simultaneously. However, the disclosed multi-workpiece processing chamber has the wall as a single body and there arises a problem that two workpiece processing stations and internal spaces are hard to clean and maintain.

In the meantime, US Patent Publication No. US2007/0281085 discloses a multi-workpiece processing chamber whose internal space is partitioned by a separable partition member and those partitioned spaces are exhausted through a single exhaust channel. Within the two internal processing spaces that are partitioned by the partition member exists each single workpiece processing station so as to process two workpieces simultaneously.

The partition member of the disclosed multi-workpiece processing chamber is separable and easy to clean and maintain. But the shape of the processing spaces that are partitioned by the partition member is asymmetric from the central part thereof. That is, the processing spaces have an asymmetric D-shape instead of a symmetric circular shape. As a result, imbalance of electric potentials occurs depending on the position from the central part and density of plasma which is generated for processing workpieces is not uniform. Since such density of plasma aggravates as the pressures become higher, the disclosed multi-workpiece processing chamber is not used at high pressures but at low pressures, being limited in use.

Also, the disclosed multi-workpiece processing chamber has a shape that is perpendicular to the common exhaust path, thereby deteriorating conductance of an exhaust gas.

Meanwhile, FIG. 1 is a schematic view of a gas supply flow of a conventional multi-workpiece processing chamber 800 which has a plurality of internal processing spaces. As shown therein, the conventional multi-workpiece processing chamber 800 includes a gas supply source 810 which supplies a processing gas, a first internal processing space 830 and a second internal processing space 840 which process workpieces, a flow rate controller (FRC) 820 which divides a processing gas supplied by the gas supply source 810 and supplies the divided gas to the first internal processing space 830 and the second internal processing space 840, respectively, and a common exhaust channel 850, through which the processing gas is exhausted after completing the processing reaction within the first and second internal processing spaces 830 and 840. Here, the FRC 820 divides a processing gas supplied by the gas supply source 810 at the same ratio to be supplied to the first internal processing space 830 and the second internal processing space 840, respectively.

However, the conventional multi-workpiece processing chamber 800 allows the processing gas to be supplied to the plurality of internal processing spaces even in the case that only one of the first and second internal processing spaces 830 and 840 performs the workpiece processing process.

Further, the processing gas is supplied to a part of the internal processing space of the conventional multi-workpiece processing chamber 800, and a plasma reaction concentrates on the part of the internal processing space where the gas is supplied. Thus, a problem arises that the density of plasma generated is not uniform across the internal processing space.

FIG. 2 is a schematic view of a common exhaust channel 850 of the conventional multi-workpiece processing chamber 800. As shown therein, the conventional multi-workpiece processing chamber 800 includes an opening/closing member 860 which is provided on a path of the common exhaust channel 850 to open and close the common exhaust channel 850. Here, the opening/closing member 860 is rotatably provided on the common exhaust channel 850, and opens and closes the common exhaust channel 850.

However, the opening/closing member 860 has such a problem that an opening/closing ratio thereof differs by each of the internal processing spaces 830 and 840 when rotating along a rotation shaft 870. That is, as shown therein, there occurs a major difference between an opening area m of the first internal processing space 830 and an opening area n of the second internal processing space 840 when the opening/closing member 860 rotates.

### DISCLOSURE

### Technical Problem

As described above, if there is a major difference in the opening/closing ratios between the plurality of internal processing spaces 830 and 840 by the opening/closing member 860, a difference between the gas exhaust rate and an exhaust pressure occurs during the equivalent time.

### Technical Solution

Accordingly, it is an aspect of the present invention to provide a multi-workpiece processing chamber and a workpiece processing system including the same which has a processing space that is divided into symmetric spaces by a separable partition member, allows an electric potential and a plasma to be generated uniformly therein to improve reproducibility of processing workpieces and yield and is usable at both low and high pressures.

Also, it is another aspect of the present invention to provide a multi-workpiece processing chamber and a workpiece processing system including the same which has an adequate channel configuration between the chamber and a common exhaust configuration to thereby improve a conductance of an exhaust gas.

Further, it is another aspect of the present invention to provide a multi-workpiece processing chamber and a gas flow control method thereof which controls a gas not to be supplied to an unused internal processing space if any of a plurality of internal processing spaces does not process workpieces.

Further, it is another aspect of the present invention to divide and supply a gas to a central part and a circumferential part of an internal processing space in order for a plasma reaction to occur uniformly within the internal processing space.

Further, it is another aspect of the present invention to open and close an opening/closing member, which is provided in a common exhaust channel, at almost equivalent opening/closing ratios with respect to a plurality of internal processing spaces.

Additional aspects and/or advantages of the present invention will be set forth in part in the description which follows and, in part, will be obvious from the description, or may be learned by practice of the present invention.

The foregoing and/or other aspects of the present invention are also achieved by providing a multi-workpiece processing chamber comprising a chamber housing which forms at least two internal processing spaces therein; at least one partition member which is provided in the chamber housing and partitions the chamber housing into at least two internal processing spaces; and the respective internal processing spaces being coupled with the partition member and having a symmetric shape to generate a processing reaction uniformly.

According to another aspect of the present invention, the chamber housing comprises a first curved surface which has a predetermined curvature, the partition member comprises a second curved surface which has the same curvature as that of the first curved surface, and the first curved surface and the second curved surface are coupled to each other and form a symmetric circle.

According to another aspect of the present invention, the chamber housing comprises a plurality of housings which is coupled to each other. According to another aspect of the present invention, the chamber housing comprises an intermediate housing which has a workpiece supporting station; an upper housing which is coupled to an upper part of the intermediate housing and forms a first curved surface; and a lower housing which is coupled to a lower part of the intermediate housing.

The foregoing and/or other aspects of the present invention are also achieved by providing a multi-workpiece processing system comprising at least one multi-workpiece processing chamber which has a plurality of internal processing spaces partitioned by a partition member; a transfer chamber, in a circumferential area of which is disposed at least one multi-workpiece processing chamber; and a workpiece transfer unit which is provided in the transfer chamber and transfers a workpiece to the internal processing spaces of the multi workpiece processing chamber.

According to another aspect of the present invention, the internal processing space is coupled with the partition member and has a symmetric shape to generate a uniform reaction.

According to another aspect of the present invention, the transfer chamber comprises a polygonal shape, and the multi-workpiece processing chamber is provided in each side of the transfer chamber.

According to another aspect of the present invention, the workpiece transfer unit comprises a spindle which is rotatably provided, a transfer arm which is coupled to the spindle and is foldable to move between a standby position and a transfer position loading the workpiece to the multi-workpiece processing chamber; and an end effector unit which is coupled to an end part of the transfer arm and comprises a plurality of end effectors which is respectively provided in a plurality of internal processing spaces of the multi-workpiece processing chamber from the transfer position.

According to another aspect of the present invention, the transfer arm is provided to move the end effector unit from the standby position to the central part of the transfer chamber.

According to another aspect of the present invention, the end effector unit is rotatably coupled to the transfer arm.

According to another aspect of the present invention, the workpiece transfer unit comprises a workpiece transfer unit for loading only which loads the workpiece to the multi-workpiece processing chamber and a workpiece transfer unit for unloading only which unloads the workpiece from the multi-workpiece processing chamber.

The foregoing and/or other aspects of the present invention are also achieved by providing a multi-workpiece processing chamber comprising a plurality of internal processing spaces which comprises a workpiece support; a first gas supply ratio controller which controls a supply ratio of a gas supplied from a gas supply source to the plurality of internal processing spaces; and a second gas supply ratio controller which is provided between the first gas supply ratio controller and the respective internal processing spaces and divides the gas supplied to the internal processing spaces and supplies gas to at least two divided parts of the internal processing spaces.

According to another aspect of the present invention, the second gas supply ratio controller divides and supplies a gas to a central part and a circumferential part of the internal processing spaces.

According to another aspect of the present invention, the second gas supply ratio controller controls a gas supply ratio so that the amount of gas supplied to the central part and the circumferential part differs.

According to another aspect of the present invention, the multi-workpiece processing chamber further comprises a common exhaust channel through which a gas is exhausted from the plurality of internal processing spaces; and a bypass controller which is provided between the first gas supply ratio controller and the second gas supply ratio controller and bypasses a path of the gas supplied to the internal processing spaces to the common exhaust channel.

According to another aspect of the present invention, the bypass controller comprises a first opening/closing valve which is provided between the first gas supply ratio controller and the second gas supply ratio controller and controls whether to supply a gas to the internal processing spaces; and a second opening/closing valve which is provided between the first gas supply ratio controller and the common exhaust channel and controls whether to supply a gas to the common exhaust channel.

### ADVANTAGEOUS EFFECTS

As described above, the multi-workpiece processing system according to the present invention includes a plurality of multi-workpiece processing chambers having a plurality of internal processing spaces. Thus, a plurality of workpieces may be processed.

As described above, the multi-workpiece processing chamber according to the present invention is partitioned into a plurality of internal processing spaces by a partition member, which is symmetric by the coupling of the partition member and the chamber. Thus, electric, potentials and plasma are generated uniformly across the internal processing spaces to thereby improve uniformity in processing workpieces.

As the plasma is generated uniformly, the multi-workpiece processing chamber may be used at not only low pressures but also high pressures.

The multi-workpiece processing chamber includes a common exhaust channel to commonly exhaust a processing gas within the plurality of internal processing spaces, and the common exhaust channel is adequately provided, thereby improving conductance of the exhaust gas.

A chamber housing and the partition member of the multi-workpiece processing chamber according to the present invention are coupled, and thus easy to clean and maintain.

As a second gas supply ratio controller of the multi-workpiece processing chamber according to the present invention divides and supplies a gas to a central part and a circumferential part of the internal processing spaces, a plasma reaction may be uniformly generated within the internal processing spaces.

A plurality of opening/closing valves may bypass the gas directly to the common exhaust channel instead of supplying the gas to the internal processing spaces if one of the plurality of internal processing spaces does not process workpieces.

A first opening/closing member and a second opening/closing member are provided on an exhaust path of the common exhaust channel so that the respective internal processing spaces are spatially isolated and the speed and pressure of the exhaust gas may be maintained uniformly.

### DESCRIPTION OF DRAWINGS

The above and/or other aspects of the present invention will become apparent and more readily appreciated from the following description of the embodiments, taken in conjunction with the accompany drawings of which:

FIG. 1 is a schematic view which briefly illustrates a gas supply process of a conventional multi-workpiece processing chamber;

FIG. 2 is a schematic view which briefly illustrates a configuration of an opening/closing member of a common exhaust channel of the conventional multi-workpiece processing chamber;

FIG. 3 is a schematic view which briefly illustrates a configuration of a multi-workpiece processing system according to an exemplary embodiment of the present invention;

FIG. 4 is a perspective view which illustrates a configuration of a multi workpiece processing chamber according to the present invention;

FIG. 5 is a plan view which illustrates a plan configuration of the multi-workpiece processing chamber according to the present invention;

FIG. 6 is an exploded perspective view which illustrates an exploded configuration of the multi-workpiece processing chamber according to the present invention;

FIG. 7 is a partial sectional perspective view which illustrates a partial configuration of the multi-workpiece processing chamber in FIG. 2;

FIG. 8 is a sectional view which illustrates a sectional configuration of the multi-workpiece processing chamber, taken along line ?-? in FIG. 5;

FIG. 9 is a sectional view which illustrates a configuration of a common exhaust channel of the multi-workpiece processing chamber according to the present invention;

FIG. 10 is a sectional view of the multi-workpiece processing chamber according to another exemplary embodiment of the present invention;

FIG. 11 is a sectional view of the multi-workpiece processing chamber which is coupled with a plasma source unit according to the present invention;

FIG. 12A is a schematic view which illustrates a configuration of an opening/closing member of the multi-workpiece processing chamber according to the present invention;

FIG. 12B is a schematic view which illustrates a transformational example of the opening/closing member of the multi-workpiece processing chamber according to the present invention;

FIG. 13 is a sectional view which illustrates a configuration of a second opening/closing member of a common exhaust channel of the multi-workpiece processing chamber according to the present invention;

FIG. 14 is a schematic view which briefly illustrates a configuration of an opening/closing member adjustor of the multi-workpiece processing chamber according to the present invention;

FIG. 15 is a schematic view which illustrates a transformational example of the opening/closing member adjustor of the multi-workpiece processing chamber according to the present invention;

FIG. 16 is a block diagram which briefly illustrates a gas flow configuration of the multi-workpiece processing chamber according to the present invention;

FIG. 17 is a block diagram which briefly illustrates a transformational example of the gas flow configuration of the multi-workpiece processing chamber according to the present invention;

FIG. 18 is a flowchart which illustrates a gas flow process of the multi-workpiece processing chamber according to the present invention;

FIG. 19 is a perspective view of a transformational example of the multi-workpiece processing chamber according to the present invention;

FIG. 20 is a sectional view which illustrates a common exhaust channel of the multi-workpiece processing chamber according to another exemplary embodiment of the present invention;

FIG. 21 is a schematic view which briefly illustrates a distribution of electric potentials within an internal processing space of the multi-workpiece processing chamber according to the present invention;

FIG. 22 is a graph which illustrates a distribution status of electric potentials within the internal processing chamber in FIG. 20;

FIG. 23 illustrates a workpiece transfer process of the multi-workpiece processing chamber according to the present invention;

FIG. 24 is a schematic view which illustrates a configuration of a workpiece transfer unit according to another exemplary embodiment of the present invention;

FIG. 25 is a schematic view which illustrates a configuration of a workpiece transfer unit according to another exemplary embodiment of the present invention; and

FIG. 26 is a schematic view which illustrates a configuration of a workpiece transfer unit according to another exemplary embodiment of the present invention.

### BEST MODE

Hereinafter, exemplary embodiments of the present invention will be described with reference to accompanying drawings, wherein like numerals refer to like elements and repetitive descriptions will be avoided as necessary. Exemplary embodiments of the present invention may be changed in various shapes, and it should not be interpreted that the scope of the present invention is limited to the exemplary embodiments described in detail hereinbelow. These exemplary embodiments are provided to fully explain the present invention to the skilled in the art. Accordingly, shapes of elements in the drawings may be overdrawn to provide more accurate explanation. Detailed description on known functions and configurations which are determined to possibly make the essential points of the present invention vague is omitted.

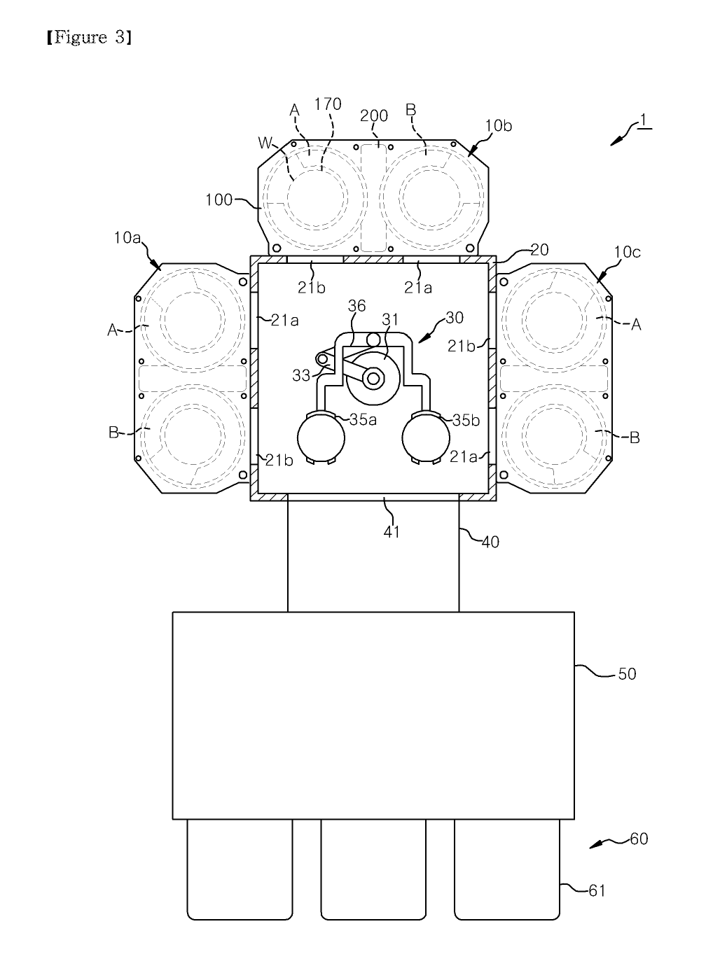

FIG. 3 is a schematic view which illustrates a configuration of a multi-workpiece processing system according to the present invention. A multi-workpiece processing system 1 according to an exemplary embodiment of the present invention includes at least one of multi-workpiece processing chambers 10a, 10b and 10c which has a plurality of internal processing spaces A and B that is partitioned by a partition member 200, leaving a transfer chamber 20 between the multi-workpiece processing chambers 10a, 10b and 10c. A workpiece transfer unit 30 is provided in the transfer chamber 20 to transfer workpieces to the plurality of the multi-workpiece processing chambers 10a, 10b and 10c. A buffering chamber 40 is provided in a lateral side of the transfer chamber 20 and is connected with a loadlock chamber 50. An index 60 is provided in the load lock chamber 50 and is mounted with a carrier 61.

As shown therein, the multi-workpiece processing chambers 10a, 10b and 10c are plurally provided in an circumference of the transfer chamber 20. The multi-workpiece processing chambers 10a, 10b and 10c according to the exemplary embodiment of the present invention may include first, second and third multi-workpiece processing chambers 10a, 10b and 10c along the transfer chamber 20.

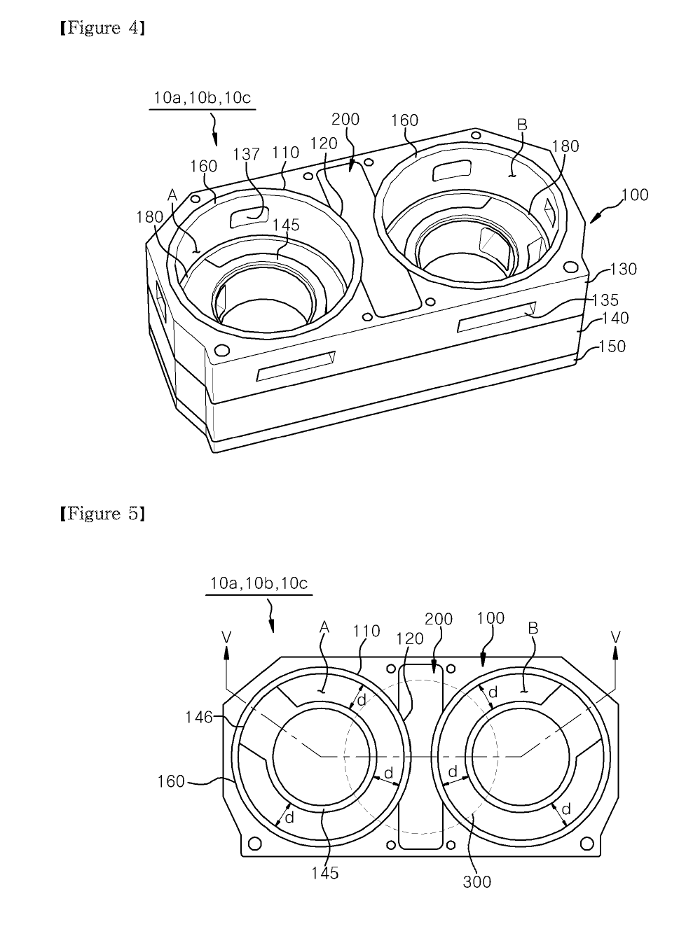

FIG. 4 is a perspective view which illustrates a configuration of the multi-workpiece processing chambers 10a, 10b and 10c according to the exemplary embodiment of the present invention. FIG. 5 is an exploded perspective view which illustrates an exploded configuration of the multi-workpiece processing chambers 10a, 10b and 10c.

As shown therein, the multi-workpiece processing chambers 10a, 10b and 10c according to the present invention includes a chamber housing 100 which has a plurality of internal processing spaces A and B, a partition member 200 which is coupled to the chamber housing 100 to partition the internal processing spaces A and B and makes the internal processing spaces A and B have symmetric shapes and a common exhaust channel 300 which is commonly coupled to the plurality of internal processing spaces A and B and exhausts a processing gas of the respective internal processing spaces A and B therethrough. The multi-workpiece processing chambers 10a, 10b and 10c according to the present invention may include an ashing chamber which removes a photoresist, a chemical vapor deposition (CVD) chamber which is configured to deposit an insulation layer, or an etching chamber which is configured to etch apertures or openings in an insulation layer to form interconnect configurations. Further, the multi-workpiece processing chambers 10a, 10b and 10c according to the present invention may include a physical vapor deposition (PVD) chamber which is configured to deposit barriers or a PVD chamber which is configured to deposit a metal layer.

The chamber housing 100 includes a plurality of internal processing spaces A and B which communicates with each other. The communication area is coupled with the partition member 200 so that the chamber housing 100 is divided into the plurality of internal processing spaces A and B. The plurality of internal processing spaces A and B is provided to have the same volume, and each single workpiece processing station 145 is provided in the internal processing spaces A and B.

As shown in FIGS. 4 and 5, the chamber housing 100 has a first curved surface 110 to form each of the internal processing spaces A and B while the partition member 200 includes a second curved surface 120 which has the same curvature as that of the first curved surface 110. If the chamber housing 100 is coupled with the partition member 200, the first curved surface 110 is coupled with the second curved surface 120 to form independent internal processing spaces A and B, respectively. The internal processing spaces A and B which are coupled with the partition member 200 form a circle which is symmetric from the center. The workpiece processing station 145 is provided in the central part of the internal processing spaces A and B. Accordingly, pitches D which are formed between the workpiece processing station 145 and the internal processing spaces A and B are equal and symmetric to each other across the internal processing spaces A and B.

Within the internal processing spaces A and B that have such a symmetric shape, the electric potential is uniformly formed during a reaction process, and a workpiece processing reaction, e.g., plasma may be generated uniformly across the internal processing spaces A and B. Therefore, workpieces may be processed at not only low pressures but also high pressures, and reproducibility and yield may improve.

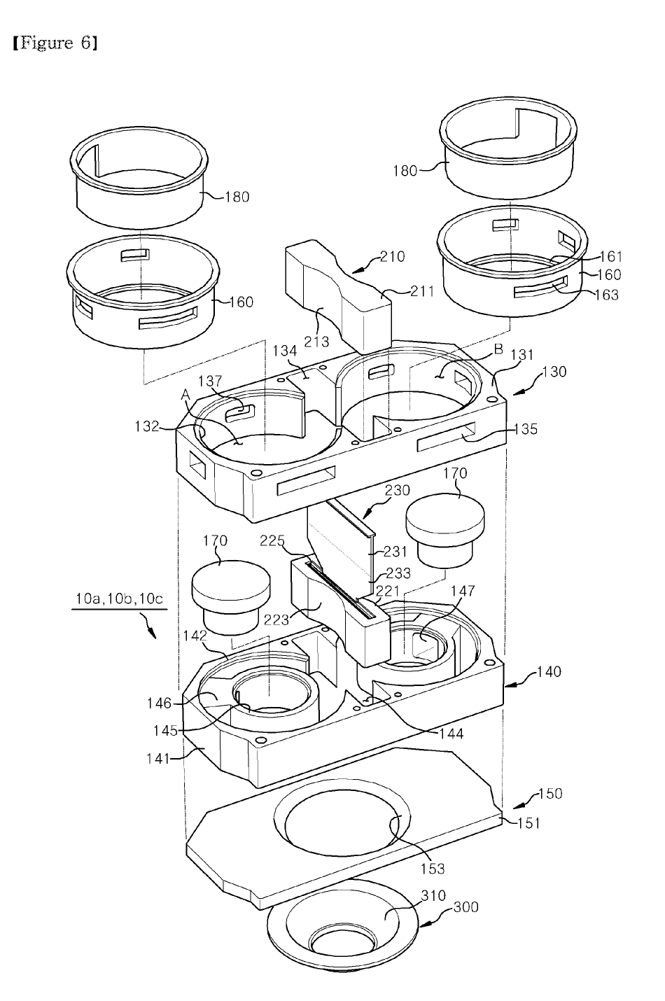

As shown in FIG. 6, the chamber housing 100 according to the exemplary embodiment of the present invention is embodied by a plurality of housings 130, 140 and 150 which is coupled with each other. The chamber housing 100 includes an upper housing 130 which has an upper first curved surface 132, an intermediate housing 140 which includes the workpiece processing station 145 and a lower housing 150 which is coupled with the common exhaust channel 300.

The upper housing 130 includes an upper housing main body 131, the upper first curved surface 132 which is formed in the upper housing main body 131, an upper partition accommodator 134 which is disposed between the upper first curved surfaces 132 and coupled with the upper partition member 200, a workpiece entrance 135 through which a workpiece enters and a monitoring unit 137 which is provided to monitor a reaction, which occurs in the internal processing spaces A and B.

The upper housing main body 131 is provided in an upper part of the intermediate housing 140 and forms the plurality of internal processing spaces A and B in which workpieces are processed. The upper housing main body 131 according to the exemplary embodiment of the present invention includes two internal processing spaces A and B which are provided in the right and left sides on the basis of the upper partition accommodator 134. Here, the respective internal processing spaces A and B which are provided in the right and left sides include the upper first curved surface 132 that has a predetermined radius. The upper first curved surface 132 is shaped like a predetermined circular arc to have the same radius from the center of the internal processing spaces A and B.

The upper partition accommodator 134 accommodates therein an upper partition 210 which has an upper second curved surface 213 (to be described later). The upper partition accommodator 134 accommodates therein the upper partition 210 and allows the upper first curved surface 132 to be coupled with the upper second curved surface 213 to thereby form the plurality of internal processing spaces A and B which is divided into the right and left sides within the chamber housing 100.

Meanwhile, two workpiece entrances 135 are provided in a front surface of the upper housing main body 131 through which a workpieces W enters. Thus, the workpiece W may enter the internal processing spaces A and B through the workpiece entrances 135. The two workpiece entrances 135 are connected to the two divided internal processing spaces A and B, respectively, and are open and closed by a slit valve (not shown), etc.

Here, the monitoring unit 137 which has a predetermined area is provided in the upper housing main body 131 to monitor a processing reaction of a workpiece occurring within the internal processing spaces A and B from the outside. The monitoring unit 137 includes a transparent material such as quartz or glass so that a user may monitor the progress of the processing reaction occurring within the internal processing spaces A and B. The monitoring unit 137 may be plurally provided along a wall surface of the upper chamber housing 100.

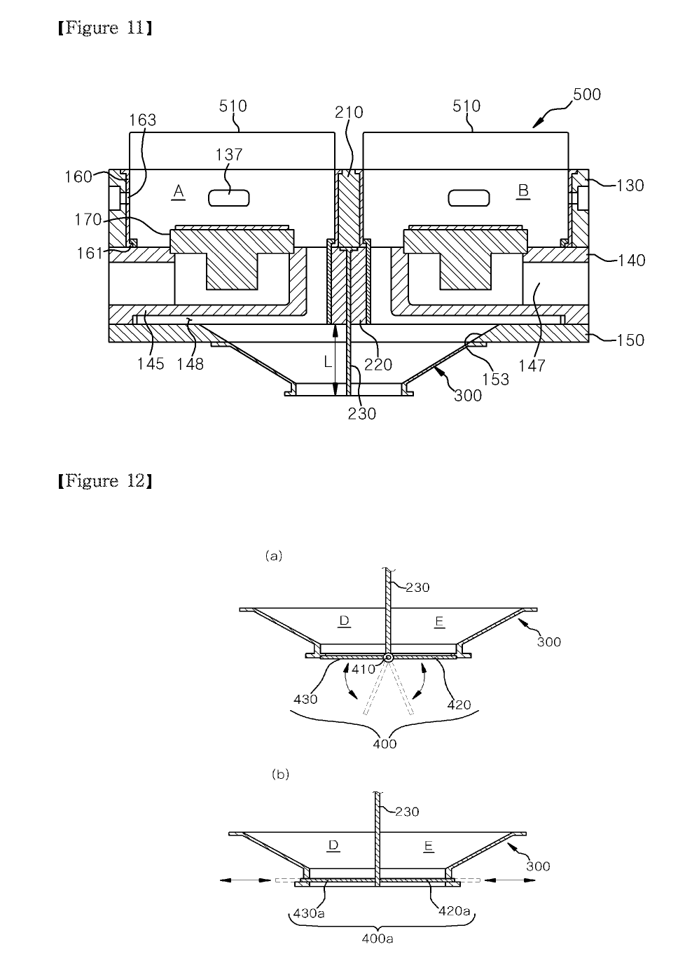

Meanwhile, the upper housing 130 further includes a source coupler (not shown) which is coupled with a plasma source unit 500 (refer to FIG. 11) that will be described later. The source coupler is provided to make the plasma source unit 500 coupled with the upper housing 130 to be open and closed or may be provided in other shapes depending on the shape of the plasma source 510.

The intermediate housing 140 is provided in a lower part of the upper housing 130 and includes the workpiece processing station 145. The intermediate housing 140 includes an intermediate housing main body 141, the workpiece processing station 145 which is coupled to a communication wall 146 of the intermediate housing main body 141, a gas discharge path 148 which is provided in the circumferential part of the workpiece processing station 145 and an intermediate partition accommodator 144.

The intermediate housing main body 141 is integrally formed with the workpiece processing station 145 and includes an intermediate first curved surface 142 which is formed in the circumferential part of the workpiece processing station 145 and has the same curvature as that of the upper first curved surface 132 of the upper housing main body 131. The intermediate first curved spaces 142 are provided in opposite sides of the intermediate housing main body 141. An intermediate partition accommodator 144 is provided between a pair of intermediate first curved surfaces 142. The intermediate partition accommodator 144 accommodates therein an intermediate partition member 200 which has an intermediate second curved surface 223 that is coupled with the intermediate first curved surface 142 and completes a symmetric shape of the internal processing spaces A and B.

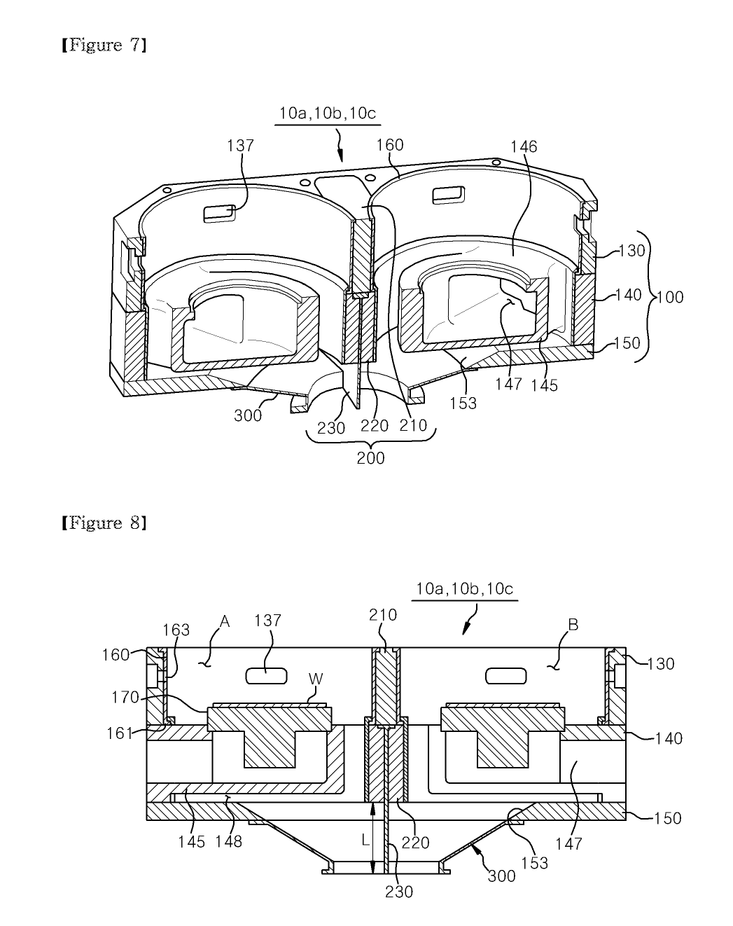

As shown in FIGS. 6 to 8, the workpiece processing station 145 is formed by being coupled with the communication wall 146 of the intermediate housing main body 141. The workpiece processing station 145 is spaced at predetermined heights from a bottom surface of the chamber housing 100. The workpiece processing station 145 is formed in the communication wall 146 of the intermediate housing main body 141 and has a space independent from the internal processing spaces A and B. Since the workpiece processing station 145 is spaced from the bottom surface of the chamber housing 100 instead of being coupled to the bottom surface thereof, the common exhaust channel 300 which will be described later may be adequately provided in the bottom surface of the chamber housing 100.

A workpiece support 170 is coupled with an upper part of the workpiece processing station 145 and blocks an internal part of the workpiece processing station 145 from the internal processing spaces A and B. As a result, the inside of the workpiece processing station 145 maintains an atmospheric pressure which is independent from the internal processing spaces A and B in a vacuum. The workpiece processing station 145 may be connected with a utility means such as a workpiece lifting means (not shown) and a power supply means (not shown) through an opening 147 which is formed in the communication wall 146 of the intermediate housing main body 141.

In a circumferential part between the workpiece processing station 145 and the intermediate housing main body 141 is formed the gas discharge path 148 through which a processing gas is discharged after the workpiece processing reaction is finished from the internal processing spaces A and B. The gas discharge path 148 is connected with the common exhaust channel 300 below the workpiece processing station 145.

Here, an exhaust gas baffle (not shown) which has a porous configuration is provided in the gas discharge path 148 to exhaust the gas perpendicularly to the common exhaust channel 300 after the processing of the workpieces. The exhaust gas baffle is provided to be coupled with the workpiece processing station 145.

The workpiece processing station 145 is provided in a central part of the intermediate housing main body 141 to have the same pitch d as that of the intermediate housing main body 141.

The lower housing 150 is provided in the lower part of the intermediate housing 140 and connected with the common exhaust channel 300. As a result, the processing gas is discharged to the common exhaust channel 300 after passing through the gas discharge path 148 of the intermediate housing 140. The lower housing 150 includes a lower housing main body 151 which forms a bottom surface of the chamber housing 100 and an exhaust channel coupler 153 which is provided in the lower housing main body 151 and coupled with the common exhaust channel 300. The exhaust channel coupler 153 corresponds to the size of the common exhaust channel 300. The exhaust channel coupler 153 preferably has an inclination corresponding to an inclination angle of an inclined surface 310 of the common exhaust channel 300 to improve a conductance of an exhaust gas.

Meanwhile, a coupling means (not shown) is provided to couple the upper housing 130, the intermediate housing 140 and the lower housing 150. The coupling means may include known coupling means including pins, bolts/nuts, hooked coupling, etc.

At least one sealing member (not shown) is provided in the coupling area of the upper housing 130, the intermediate housing 140 and the lower housing 150 to make the internal processing spaces A and B remain sealed.

An upper liner 160 and an intermediate liner 180 are provided in the upper housing 130 and the intermediate housing 140, respectively, to cover an internal surface of the internal processing spaces A and B. The upper liner 160 is coupled with the internal surface of the internal processing spaces A and B which are formed by the coupling of the upper first curved surface 132 of the upper housing main body 131 and the upper second curved surface 213 of the upper partition 210. The upper liner 160 includes an intermediate liner coupler 161 coupled to the intermediate liner 180 (to be described later) and a monitoring window 163 which corresponds to the monitoring unit 137 of the upper housing 130.

The intermediate liner coupler 161 includes a step in the internal surface thereof so that the intermediate liner 180 is held by the step.

The intermediate liner 180 is coupled with the internal surface of the internal processing spaces A and B which are formed by the coupling of the intermediate first curved surface 142 of the intermediate housing main body 141 and the intermediate second curved surface 223 of the intermediate partition 220. The intermediate liner 180 is loaded onto the intermediate liner coupler 161 of the upper liner 160 to fix the position thereof.

The upper liner 160 and the intermediate liner 180 are provided in the internal surface of the internal processing spaces A and B to prevent the internal surface of the internal processing spaces A and B from being damaged or worn by ion collision of plasma. The upper liner 160 and the intermediate liner 180 may be replaced with new ones if internal surfaces thereof are damaged or worn by a plurality of processing reactions.

Meanwhile, the multi-workpiece processing chambers 10a, 10b and 10c according to the exemplary embodiment of the present invention includes a plurality of liners such as upper liners and intermediate liners for the purpose of convenient assembly and maintenance, but not limited thereto. Alternatively, the multi-workpiece processing chambers 10a, 10b and 10c may include a single liner.

The partition member 200 is coupled with the chamber housing 100 and partitions the chamber housing 100 into two internal processing spaces A and B. The partition member 200 is coupled with the first curved surface 110 of the chamber housing 100 to complete the internal processing spaces A and B that have a symmetric shape.

The partition member 200 is provided by the coupling of a plurality of partitions 210, 220 and 230. The partition member 200 includes an upper partition 210 which is coupled to the upper housing 130, an intermediate partition 220 which is coupled to the intermediate housing 140 and an exposing partition 230 which penetrates and is coupled to the intermediate partition 220. The partition member 200 is connected to a ground terminal (not shown) so that the respective internal processing spaces A and B form uniform electric potentials.

The upper partition 210 includes an upper partition main body 211 which is accommodated in and coupled to the upper housing main body 131 and an upper second curved surface 213 which is formed in the upper partition main body 211 and coupled with the upper first curved surface 132 of the upper housing main body 131. The upper partition main body 211 corresponds to the shape of the upper partition accommodator 134 of the upper housing main body 131 and is fitted into the upper partition accommodator 134. The upper second curved surface 213 is provided in opposite sides of the upper partition main body 211. The upper second curved surface 213 has the same curvature as that of the upper first curved surface 132 so that the internal processing spaces A and B which are formed by the coupling of the upper first curved surface 132 and the upper second curved surface 213 has a circular shape that has the same radius from the center. The upper partition 210 may be forcedly fitted or coupled to the upper housing main body 131 by known coupling means.

Meanwhile, as shown in FIG. 11, an upper partition main body 211 according to another exemplary embodiment of the present invention may include a slit 215 which has a predetermined length: The slit 215 reduces a mutual interference of static electricity, electric potential, etc. which occurs in the plurality of internal processing spaces A and B. That is, if different electric potentials are applied to the plurality of internal processing spaces A and B, neighboring electric potentials of the internal processing spaces A and B may affect the applied electric potentials. Here, the slit 215 may reduce such interference and impact by isolating the internal processing spaces A and B.

The intermediate partition 220 is accommodated in and coupled to the internal housing 140. The intermediate partition 220 includes an intermediate partition main body 221 which has an intermediate second curved surface 223 and an exposing partition accommodation hole 225 which is formed in the intermediate partition main body 221 and coupled with the exposing partition 230. The intermediate partition main body 221 is accommodated in and coupled to the intermediate partition accommodator 144 of the intermediate housing main body 141. The intermediate second curved surface 223 is coupled with the intermediate first curved surface 142 of the intermediate housing 140 and completes the internal processing spaces A and B which have a symmetric shape.

The exposing partition accommodation hole 225 has a width corresponding to the thickness of the exposing partition 230, which is inserted into the exposing partition accommodation hole 225. Meanwhile, like the upper partition 210, the intermediate partition 220 may also include a communication hole (not shown) and a slit (not shown).

The exposing partition 230 is inserted into the intermediate partition 220 and divides the common exhaust channel 500 into two parts. The exposing partition 230 includes an accommodation area 231 which is accommodated in the intermediate partition 220 and an exposing area 233 which is exposed to the outside of the intermediate partition 220 and coupled with the common exhaust channel 300. The exposing area 233 may have an inclined surface or a curved surface corresponding to the shape of the common exhaust channel 300. A hook coupler 135 is provided in the exposing partition 230 to fix the position thereof when inserted into the exposing partition accommodation hole 225. The hook coupler 135 extends from the accommodation area 231 and is coupled to the exposing partition accommodation hole 225.

As shown in FIGS. 5 and 6, the exposing partition 230 is accommodated in the intermediate partition 220 and the upper partition 210 is stacked on the intermediate partition 220. The length of the partitions 210, 220 and 230 may be adjusted corresponding to the length of the chamber housing 100.

Here, the exposing length of the exposing partition 230 which is exposed to the lower part of the intermediate partition 220 is adjustable. With the exposing length L adjusted, the volume and pace of the processing gas which is exhausted to the common exhaust channel 300 may be controlled.

At least one communication hole (not shown) may be provided in the partition member 200 to connect the two internal processing spaces A and B which are partitioned by the partition member 200. A sectional shape of the communication hole may vary including a circular shape, a elliptical shape, a rectangular shape having round corners, a circular arc shape, etc. The communication hole may be formed in a horizontal or vertical slit. The communication hole may be provided in the upper partition 210 or the lower partition 220. Also, the communication hole may be plurally provided in one of the upper part, the central part and the lower part of the upper partition 210.

Each of the communication holes may preferably be provided not to face each other. That is, each of the communication holes is provided in different positions so that the two divided internal processing spaces A and B do not directly face each other.

The communication hole spatially connects the two internal processing spaces A and B which are partitioned by the partition member 200 and allows the two internal processing spaces A and B to maintain the same pressure and atmosphere. As the communication hole is provided in the partition member 200, it may be easily maintained.

Meanwhile, the partition member 200 according to the exemplary embodiment of the present invention is plurally provided for easy cleaning and maintenance, but not limited thereto. Alternatively, the partition member 200 may be provided as a single member that has a second curved surface 120 corresponding to the first curved surface 110 of the chamber housing 100. In some cases, the partition member 200 may be divided into at least four parts.

The common exhaust channel 300 is provided below the chamber housing 100 and provides a flow path for exhausting the processing gas after the completion of the processing reaction. The common exhaust channel 300 is provided in the central part of the plurality of internal processing spaces A and B and is divided into a first exhaust channel D and a second exhaust channel E by the exposing partition 230.

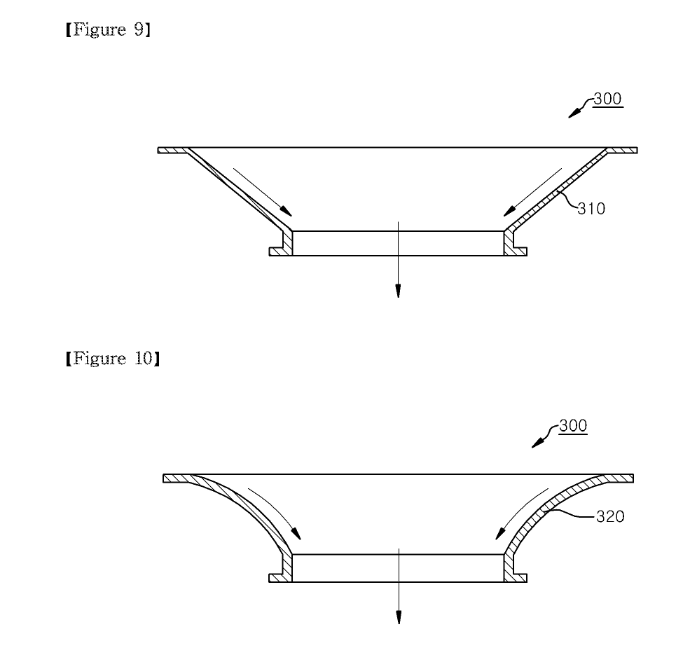

As shown in FIG. 9, the common exhaust channel 300 according to the exemplary embodiment of the present invention includes an inclined surface 310 which is inclined to the lower housing 150. Thus, conductance of the exhaust gas may improve in a vacuum rather than the case where the common exhaust channel 300 is perpendicular to the conventional chamber housing.

Turning back to FIG. 8, the common exhaust channel 300 may include a curved surface 320 which has an adequate curvature with respect to the lower housing 150.

As shown in FIGS. 9 and 10, the common exhaust channel 300 may be coupled with a part of the lower housing 150 or as shown in FIG. 20, may include an overall inclined surface 330 which is adequately formed across the intermediate housing 140.

In the common exhaust channel 300 which is divided into the first exhaust channel D and the second exhaust channel E by the exposing partition 230 may be provided a first opening/closing member 400 to selectively open and close the exhaust channels D and E, respectively. The first opening/closing member 400 selectively opens and closes the exhaust channels D and E to spatially separate the first exhaust channel D and the second exhaust channel E. As shown in FIG. 12A, the first opening/closing member 400 may include a first rotating member 420 and a second rotating member 430 which are provided to rotate, centering on the rotating shaft 410 provided in a center of the exposing partition 230. Here, the rotating members 420 and 430 preferably rotate to a front surface of the gas flowing direction not to interfere with the flow of the processing gas.

The first opening/closing member 400 may be used to close one of the exhaust channels D and E if one of the plurality of internal processing spaces A and B may not be used or does not need to be used, thereby preventing unnecessary use of the concerned internal processing space.

As shown in FIG. 12B, a first opening/closing member 400a may include a pair of opening/closing doors 420a and 430a which are provided to slide in a transverse direction with respect to an axial direction of the exhaust channels D and E to thereby selectively open and close the exhaust channels D and E.

Other than the foregoing exemplary embodiments, the opening/closing members 400 and 400a may be realized by known technologies to selectively open and close the path.

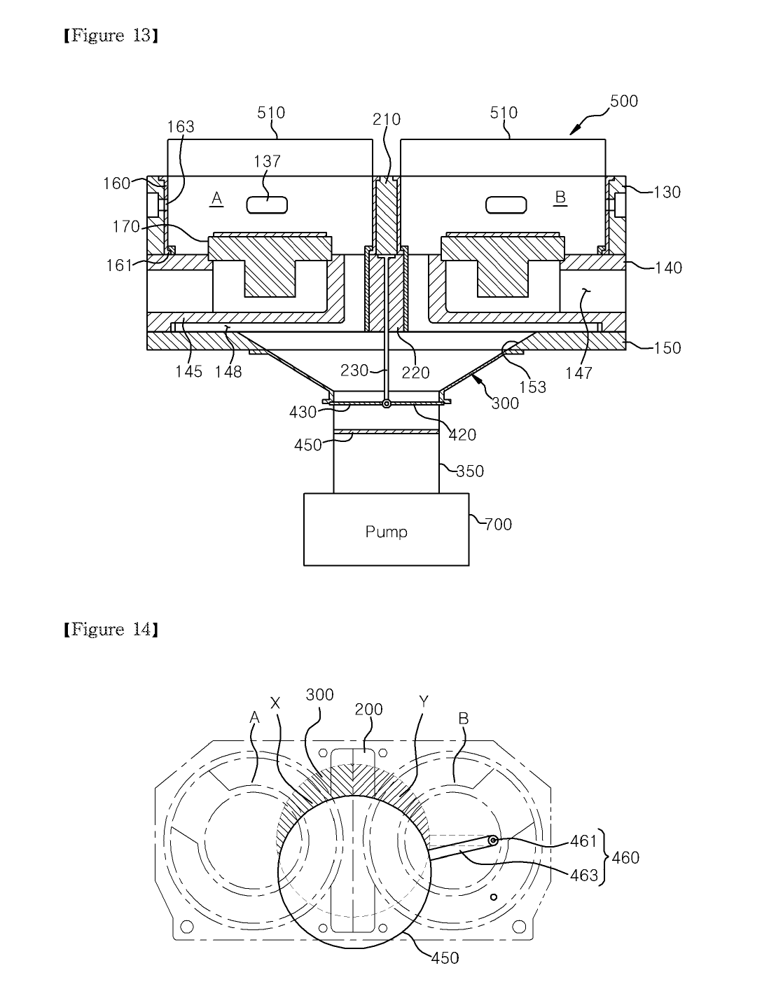

As shown in FIG. 13, the common exhaust channel 300 is connected with an exhaust pump 700 by an exhaust path 350. Here, an exhaust gas which is exhausted from the first and second exhaust channels D and E flows through the exhaust path 350 between the first opening/closing member 400 and the exhaust pump 700. A second opening/closing member 450 is provided in the exhaust path 350 which is adjacent to the exhaust pump 700 to control the flow speed of the exhaust gas by controlling the opening/closing ratio of the exhaust path 350. The opening/closing operation of the second opening/closing member 450 is controlled so that the opening/closing ratio with respect to the plurality of internal processing spaces A and B is within the range of 0.7 to 1 by the opening/closing adjustor 460.

As shown in FIG. 14, the opening/closing adjustor 460 according to the exemplary embodiment of the present invention adjusts the opening/closing extent as the second opening/closing member 450 is rotatably coupled to the exhaust path 350. To support this function, the opening/closing adjustor 460 includes a rotation shaft 461, and a link member 463 which is coupled between the rotation shaft 461 and the second opening/closing member 450 and transmits a rotation force of the rotation shaft 461 to the second opening/closing member 450. Here, the rotation shaft 461 and the link member 463 are provided so that a ratio of an opening area X of the first internal processing space A with respect to an opening area Y of the second processing space B is within the range of 0.7 to 1 by the rotation of the second opening/closing member 450. Particularly, the rotation shaft 461 and the link member 463 are provided so that the ratio of the opening area X of the first internal processing space A with respect to the opening area Y of the second internal processing area B is 1:1 when the second opening/closing member 450 opens 20% to 30% of the exhaust path 350. The rotation shaft 461 is provided in an external side of the exhaust path 350, and the link member 463 extends from the rotation shaft 461 and rotatably supports the second opening/closing member 450.

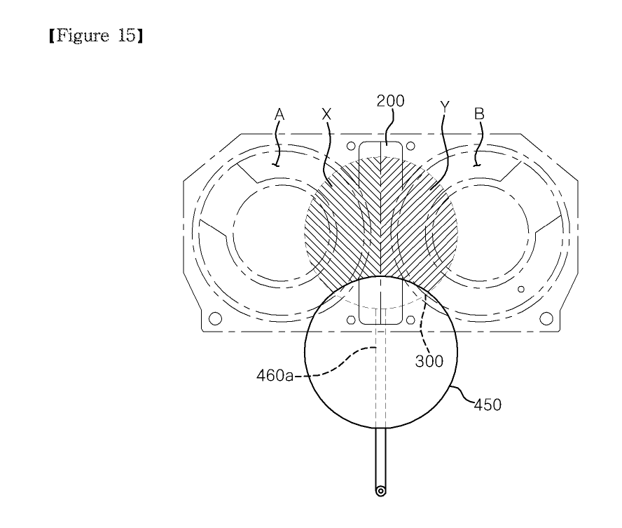

As shown in FIG. 15, an opening/closing member adjustor 460a according to another exemplary embodiment of the present invention adjusts a movement of the second opening/closing member 450 so that the second opening/closing member 450 moves linearly in a transverse direction of the exhaust path 350 and an opening area X of the first internal processing space A and an opening area Y of the second internal processing space B become equivalent. Here, the opening/closing member adjustor 460a has a strength that the opening area of the plurality of internal processing spaces A and B is maintained equally as the second opening/closing member 450 moves linearly in an axial direction of the opening/closing member adjustor 460a rather than when the second opening/closing member 450 rotates.

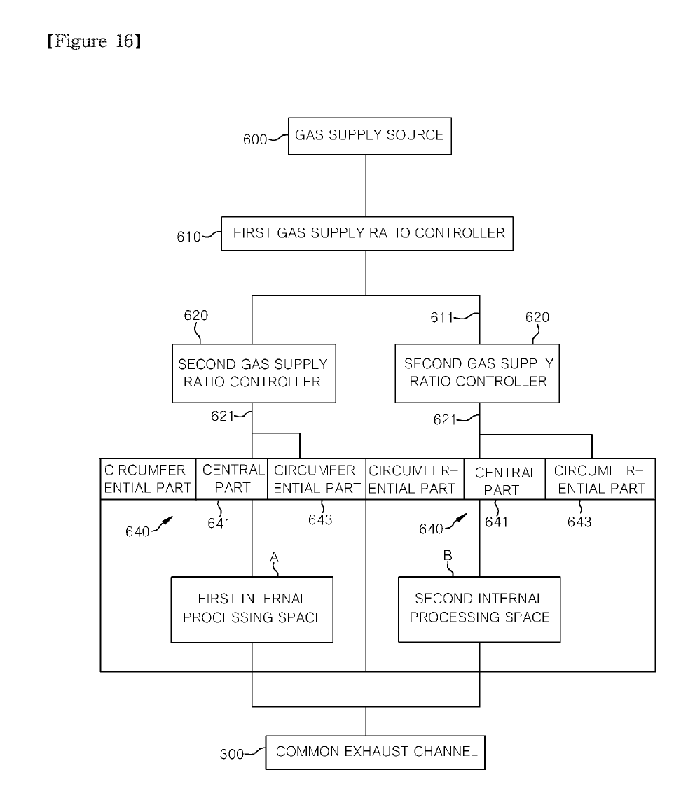

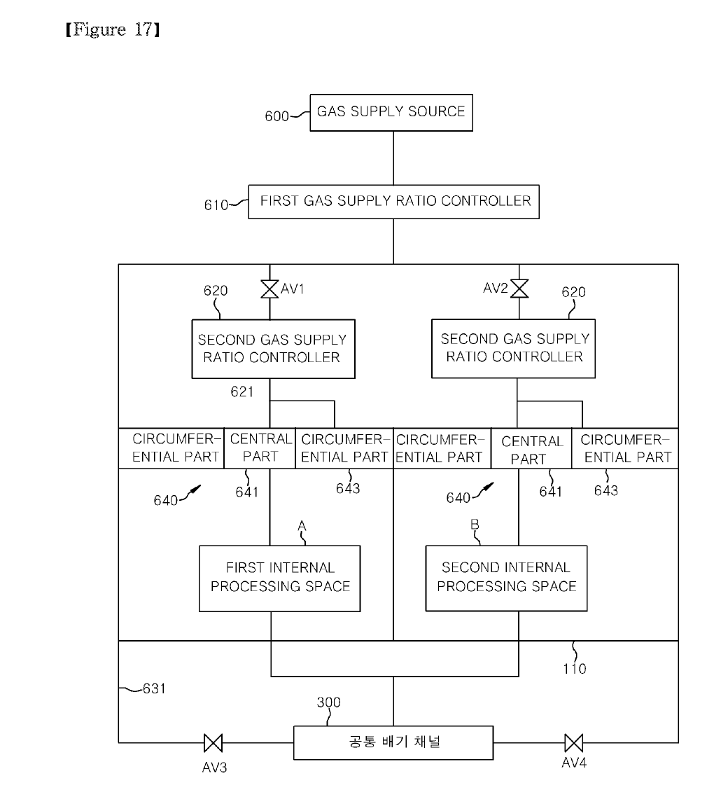

FIG. 16 is a schematic view which briefly illustrates a gas supply configuration of the multi-workpiece processing chambers 10a, 10b and 10c according to the present invention. As shown therein, the multi-workpiece processing chambers 10a, 10b and 10c include a gas supply source 600 which is provided in a lateral side of the chamber housing 100 and supplies a gas to the inside of the chamber housing 100. The gas supply source 600 includes a gas storage unit (not shown) which stores therein a gas and a supply pump (not shown) which supplies the gas from the gas storage unit to the inside of the chamber housing 100.

In a lateral side of the gas supply source 600 is provided a first gas supply ratio controller 610 which divides a gas supplied by the gas supply source 600 at a predetermined ratio and supplies the gas to the plurality of internal processing spaces A and B and a pair of second gas supply ratio controllers 620 which re-divides and supplies the gas which is divided by the first gas supply ratio controller 610 and supplied to the respective internal processing spaces A and B, according to the internal processing spaces A and B.

The first gas supply ratio controller 610 divides the gas at the predetermined ratio corresponding to the number of the plurality of internal processing spaces A and B and supplies the divided gas to the plurality of internal processing spaces A and B. If the chamber housing 100 is divided into two internal processing spaces A and B as in the exemplary embodiment of the present invention, the first gas supply ratio controller 610 divides the supplied gas at the ratio of 5:5 and supplies the gas to the two internal processing spaces A and B. The ratio of dividing the gas may be determined to be equal or different. Here, the gas which is supplied by a single gas supply source 600 is supplied to the internal processing spaces A and B, respectively through the two first gas supply paths 611 after passing through the first gas supply ratio controller 610.

The pair of second gas supply ratio controllers 620 divides and supplies the gas at the predetermined ratio to the internal processing spaces A and B, wherein the gas has been divided and supplied by the first gas supply ratio controller 610 to the internal processing spaces A and B, respectively. Here, the second gas supply ratio controller 620 may divide the gas according to the internal processing spaces A and B to be supplied thereto.

Generally, the gas includes an activated gas to incur a plasma reaction by a plasma source 510 (refer to FIG. 11). The gas is supplied to the internal processing spaces A and B through a porous shower head 640 which is provided in the upper part of the internal processing spaces A and B. The second gas supply ratio controller 620 supplies the gas by dividing the gas for a central part 641 and a circumferential part 643 of the porous shower head 640. Here, the plasma source 510 may be separately provided in the central part 641 and the circumferential part 643 depending on the type or may be provided as a single plasma source 510.

Here, the second gas supply ratio controller 620 differently controls the ratio of the gas supplied to the central part 641 of the internal processing spaces A and B and the gas supplied to the circumferential part 643 thereof. This is performed to generate a plasma reaction uniformly across the internal processing spaces A and B in consideration of the type and position of the plasma source, the density of gas supply holes of the porous shower head 640, an internal shape of the chamber housing 100, etc. The second gas supply ratio controller 620 according to the exemplary embodiment of the present invention controls the gas supply ratio to supply more gas to the circumferential part 643 rather than to the central part 641, but not limited thereto. Alternatively, the second gas ratio controller 620 may supply the gas separately to three parts of the central part, the central part and the circumferential part to uniformly generate the plasma reaction and control the gas supply ratio differently. Here, the second gas supply ratio controller 620 supplies a gas through a pair of second gas supply paths 621 to the internal processing spaces A and B.

As shown in FIG. 17, multi-workpiece processing chambers 10a, 10b and 10c according to another exemplary embodiment of the present invention include a first opening/closing valve AV1 and a second opening/closing valve AV2 provided between a first gas supply ratio controller 610 and a second gas supply ratio controller 620. The first and second opening/closing valves AV1 and aV2 bypass a gas to a common exhaust channel 300 instead of supplying the gas to an internal processing space which does not process workpieces if one of the plurality of internal processing spaces A and B does not process workpieces. A third opening/closing valve AV3 and a fourth opening/closing valve AV4 are provided on a third gas supply path 631 between the first and second opening/closing valves AV1 and AV2 and the common exhaust channel 300 to control the gas supply to the common exhaust channel 300.

The plurality of internal processing spaces A and B processes a plurality of workpieces at a time. However, in some cases, only one of the internal processing spaces A and B may process workpieces. For example, if one of the internal processing spaces A and B has an error or workpieces are transferred to only one of the plurality of internal processing spaces A and B, the workpiece may be processed by only one of the internal processing spaces A and B. In this case, the first and second opening/closing valves AV1 and AV2 control a gas not to be supplied to the internal processing spaces A and B which do not process the workpieces. If the first internal processing space A does not process the workpieces, the first opening/closing valve AV1 cuts off the gas supplied to the first internal processing space A. The gas which is not supplied to the first internal processing space A by the first opening/closing valve AV1 is directed to the common exhaust channel 300 along a gas path while the third opening/closing valve AV3 is open and allows the gas to be exhausted to the common exhaust channel 300.

Here, the plurality of opening/closing valves AV1, AV2, AV3 and AV4 is controlled whether to be open or closed by a control signal of a controller (not shown). That is, the respective opening/closing valves AV1, AV2, AV3 and AV4 are open or closed by receiving an opening/closing signal depending on whether the plurality of internal processing spaces A and B is used or not.

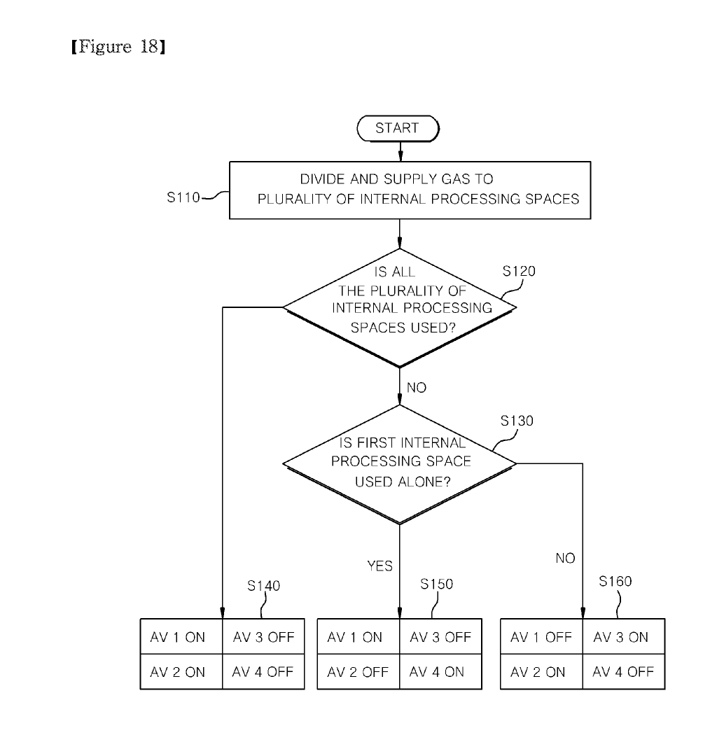

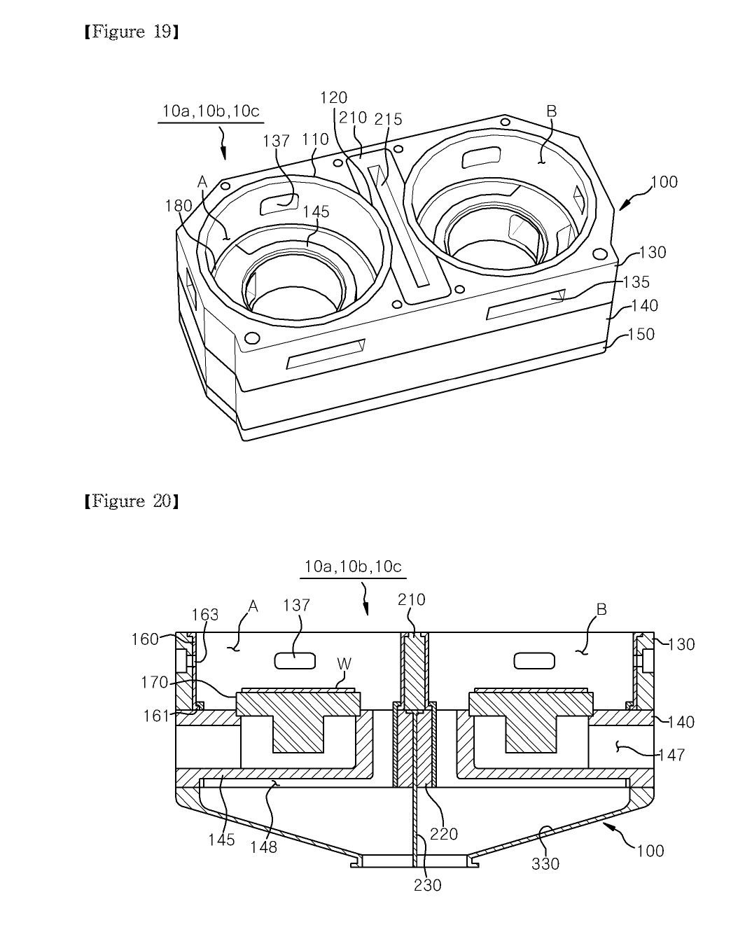

FIG. 18 is a flowchart which describes an opening/closing operation of the plurality of opening/closing valves AV1, AV2, AV3 and AV4. As shown therein, if a workpiece processing process starts, the gas supply source 600 supplies a gas. Then, the first gas supply ratio controller 610 divides the supplied gas and supplies the divided gas to the first internal processing space A and the second internal processing space B, respectively (S110). Here, the controller determines whether to process the workpiece in the plurality of internal processing spaces A and B. More specifically, the controller checks the function of the plurality of internal processing spaces A and B to determine whether to process the workpiece therein, and compares the number of workpieces transferred by the transfer chamber 20 (to be described later) and the number of the plurality of internal processing spaces A and B to determine whether there is an internal processing space that does not need to process the workpiece (S120).

If it is determined that all of the plurality of internal processing spaces A and B processes the workpiece, the controller open all the first and second opening/closing valves AV1 and AV2 to supply the gas to the first internal processing space A and the second internal processing space B, respectively. Here, the third and fourth opening/closing valves AV3 and AV4 are closed not to flow the gas to the common exhaust channel 300 (S140).

If it is determined that only the first internal processing space A is used, instead of the plurality of internal processing spaces A and B is used (S130), the controller controls the gas to be supplied to the first internal processing space A and not to be supplied to the second internal processing space B. Thus, the first opening/closing valve AV1 is open to supply the gas to the first internal processing space A while the second opening/closing valve AV2 is closed not to supply the gas to the second internal processing space B and to bypass the gas to the common exhaust channel 300. Here, the third opening/closing valve AV3 is closed not to supply the gas to the common exhaust channel 300 while the fourth opening/closing valve Av4 is open to supply the gas which is cut off by the second opening/closing valve AV2, to the common exhaust valve 300 (S150).

Meanwhile, in the case that only the second internal processing space B is used, instead of all the plurality of internal processing spaces A and B is used (S130), the controller controls the gas to be supplied to the second internal processing space B and not to be supplied to the first internal processing space A. Thus, the first opening/closing valve AV1 is closed not to supply the gas to the first internal processing space A while the second opening/closing valve AV2 is open to supply the gas to the second internal processing space B. Here, the fourth opening/closing valve AV4 is closed not to supply the gas to the common exhaust channel 300 while the third opening/closing valve AV3 is open to supply the gas which is cut off by the first opening/closing valve AV1, to the common exhaust channel 300 (S150).

If the gas is supplied to each of the internal processing spaces A and B, the second gas supply ratio controller 620 divides and supplies the gas to the central part 641 and the circumferential part 643. Accordingly, the plasma reaction occurs uniformly across the central part 641 and the circumferential part 643, and the gas is supplied to the exhaust pump 700 through the gas discharge path 148 within the internal processing spaces A and B and then through the common exhaust channel 300 after the plasma reaction is completed.

As described above, in the multi-workpiece processing chambers 10a, 10b and 10c according to the present invention, the second gas supply ratio controller 620 divides and supplies the gas to the central part and the circumferential part of the internal processing spaces A and B to thereby enable the plasma reaction to uniformly occur within the internal processing spaces A and B.

Also, if one of the plurality of internal processing spaces A and B does not process workpieces, the plurality of opening/closing valves may bypass the gas directly to the common exhaust channel instead of supplying the gas to the internal processing spaces.

As the first and second opening/closing members are provided on the exhaust path of the common exhaust channel, each of the internal processing spaces is isolated and the flow speed and pressure of the exhaust gas may be maintained uniformly.

Referring to FIGS. 6 to 8 and 20, the assembly method and multi-workpiece processing method of the multi-workpiece processing chambers 10a, 10b and 10c according to the present invention will be described.

First, the lower housing 150 is coupled to the intermediate housing 140, and then the intermediate partition accommodator 144 of the intermediate housing 140 is coupled to the intermediate partition 220. The exposing partition 230 is inserted into the coupled intermediate partition 220.

The intermediate housing 140 is then coupled to the upper housing 130, and then the upper housing 130 is coupled with the upper partition 210. The upper first curved surface 132 and the upper second curved surface 213 are coupled to complete the internal processing spaces A and B which are symmetric. The upper liner 160 is coupled to the internal wall surface of the completed internal processing spaces A and B. The intermediate liner coupler 161 of the upper liner 160 is coupled with the intermediate liner 180. Then, the upper housing 130 is coupled with the plasma source unit 500.

The plasma source unit 500 includes the plasma source 510, which supplies plasma to each of the internal processing spaces A and B. The plasma source 510 generates plasma to process workpieces. The plasma source 510 may include a capacity coupled plasma source, an inductively coupled plasma source, a transformer coupled plasma source, etc. The plasmas source 510 may be determined depending on the type of workpieces processed by the plasma source 510.

The plasma source unit 500 may be coupled with the gas supply source 600 to supply a reaction gas to thereby generate plasma.

If the assembly of the multi-workpiece processing chambers 10a, 10b and 10c is completed, the workpiece W is loaded onto the workpiece support 170 through the workpiece entrance 135. The plasma source 510 generates plasma to process the surface of the workpiece W. As the internal processing spaces A and B form a symmetric circle by the first and second curved surfaces 110 and 120, the density of plasma becomes uniform across the internal processing spaces A and B. Accordingly, the workpiece W may be uniformly processed in all areas thereof. If the plasma reaction is finished, the processing gas is discharged to the outside through the gas discharge path 148 and the common exhaust channel 300.

The multi-workpiece processing chamber according to the exemplary embodiment of the present invention has a circular symmetric shape by the coupling of the chamber housing and the partition, but not limited thereto. Alternatively, the multi-workpiece processing chamber may include a rectangular shape in some cases.

The multi-workpiece processing chamber according to the exemplary embodiment of the present invention has two internal processing spaces, but not limited thereto. Alternatively, the multi-workpiece processing chamber according to the exemplary embodiment of the present invention may include three or more internal processing spaces.

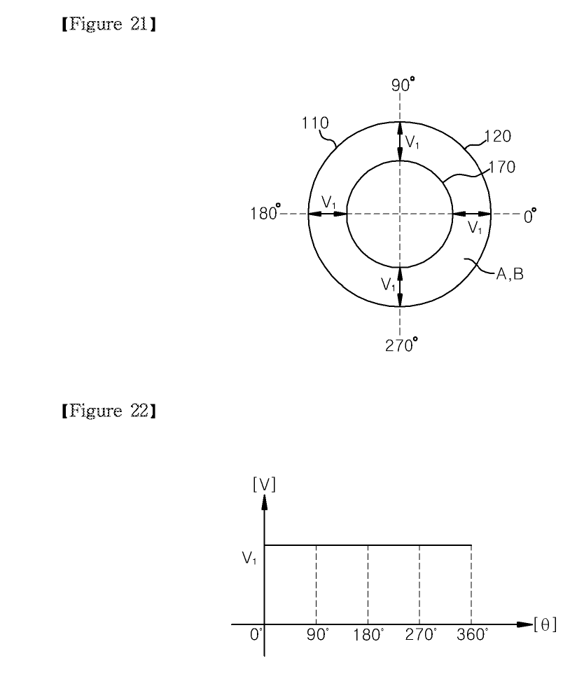

FIG. 21 illustrates an electric potential which is generated between an external wall of the internal processing spaces A and B formed by the coupling of the first and second curved surfaces 110 and 120 and the workpiece processing station 170 in the multi-workpiece processing chamber according to the present invention. As the external wall of the internal processing spaces A and B is shaped like a symmetric circle by the coupling of the first and second curved surfaces 110 and 120 and the partition member 200 is connected to the ground, the value of the electric potential is zero. The workpiece processing station 170 which is spaced from the external wall at predetermined intervals has the same electric potential in any area by the symmetric shape with the internal processing spaces. That is, as shown in FIG. 22, the value of the electric potential in the area where the angle θ is 90 degrees with respect to the base line and the value of the electric potential in the area where the angle θ is 180 degrees is the same, i.e., V1, which applies uniformly across the area.

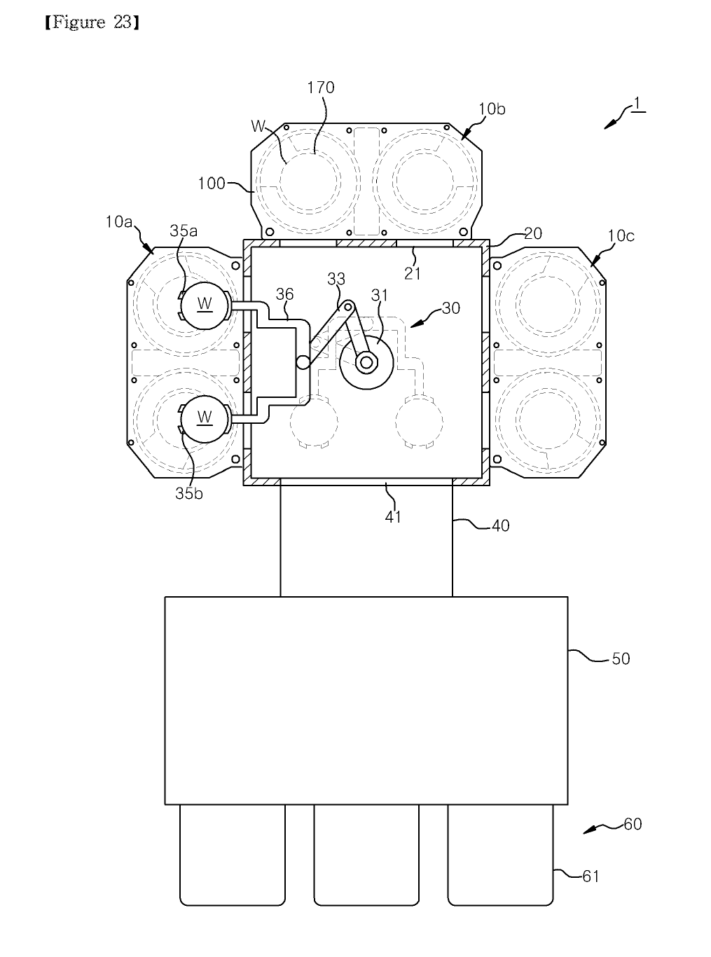

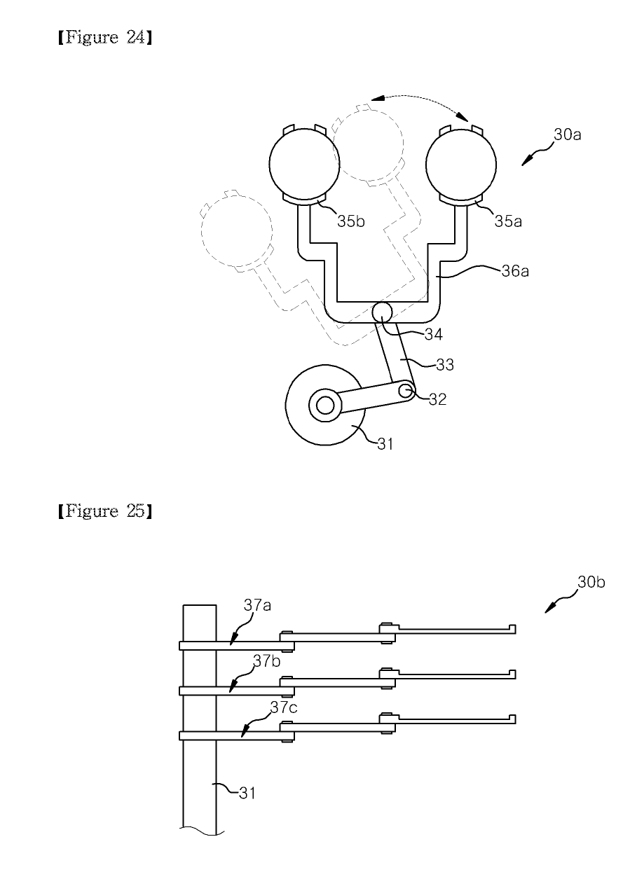

FIG. 23 illustrates a workpiece transfer operation of the workpiece transfer unit 30. The workpiece transfer unit 30 receives the workpiece from the buffering chamber 40 and transfers the workpiece to the workpiece support 170 of the multi-workpiece processing chambers 10a, 10b and 10c. The workpiece transfer unit 30 may enter the internal processing spaces A and B through the second workpiece entrances 21a and 21b of the transfer chamber 20 and the workpiece entrance 135 of the multi-workpiece processing chambers 10a, 10b and 10c. Here, the workpiece entrance 135 and the second workpiece entrances 21a and 21b are controlled by the slit valve as to whether to be open or closed.

The workpiece transfer unit 30 according to the exemplary embodiment of the present invention receives a plurality of workpieces from the buffering chamber 40 at the same time and transfers the workpieces to the multi-workpiece processing chambers 10a, 10b and 10c. The workpiece transfer unit 30 rotates and sequentially transfers the plurality of workpieces to the plurality of multi-workpiece processing chambers 10a, 10b and 10c.

The workpiece transfer unit 30 includes a spindle 31 which is rotatably provided in a central part of the transfer chamber 20, a transfer arm 33 which is foldably coupled to the spindle 31 and an end effector unit 36 which is coupled to an end part of the transfer arm 33 and includes a plurality of end effectors 35a and 35b supporting the workpiece. The spindle 31 is rotatably provided in the central part of the transfer chamber 20. The spindle 31 rotates and makes the transfer arm 33 coupled thereto transfer the workpieces to the first, second and third multi-workpiece processing chambers 10a, 10b and 10c.

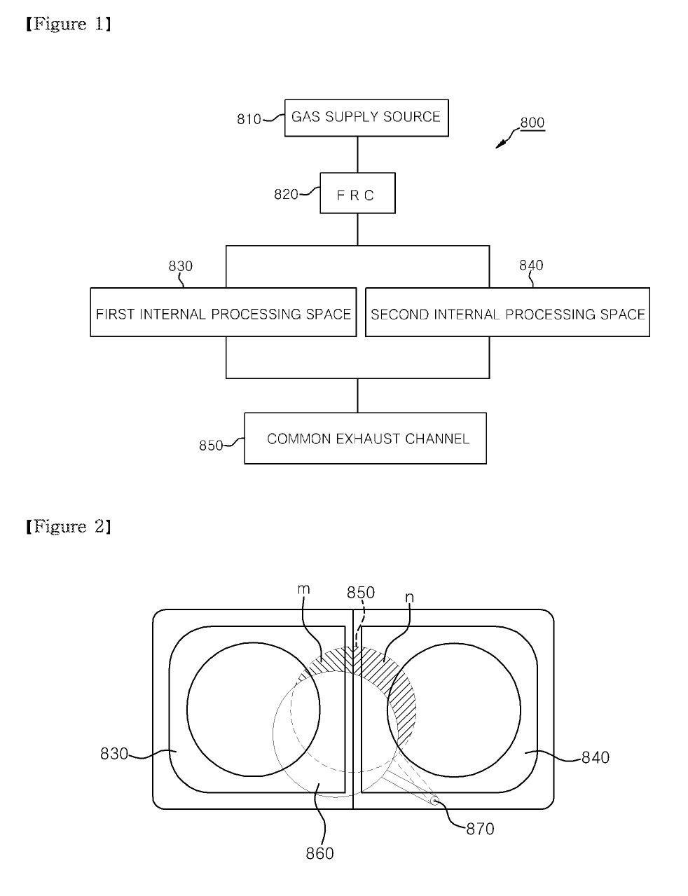

The transfer arm 33 is foldably coupled to the spindle 31. As shown in FIG. 1, the transfer arm 33 maintains the folded state in a standby mode loading the workpiece so that the end effector unit 36 stands by in the central part of the transfer chamber 20. As shown in FIG. 15, the transfer arm 33 unfolds and extends so that the end effector units 35a and 35b are positioned in the internal processing spaces A and B if transferring the workpiece to the multi-workpiece transfer chamber 20. To support this function, at least two link members are rotatably linked to the transfer arm 33.

The transfer arm 33 according to the exemplary embodiment of the present invention, as a single arm, foldably supports the end effector unit 36, but not limited thereto. Alternatively, the transfer arm 33 may include a dual arm which includes a pair of transfer arms to transfer workpieces stably if the workpieces become larger.

The end effector unit 36 is coupled to the transfer arm 31, and loads the workpiece thereon. The end effector unit 36 includes a pair of end effectors 35a and 35b which is separated in left and right sides. The end effector unit 36 is integrally coupled to an end part of the transfer arm 33 so that the plurality of end effectors 35a and 35b loads and unloads the workpiece at the same time to the workpiece support 170 provided in the plurality of internal processing spaces A and B if the transfer arm 33 is folded or unfolded. The end effector unit 36 is bent from the center to the left and right sides in predetermined length and includes the end effectors 35a and 35b formed in an end part thereof.

The end effectors 35a and 35b are provided in opposite sides of the end effector unit 36 and the workpiece is supported by the upper surface of the end effectors 35a and 35b. The end effectors 35a and 35b has an opening whose first side is open, and is shaped like a horseshoe to lay the side of the workpiece on the upper surface. The opening is provided for a lift pin (not shown) installed in the workpiece support 170 to enter therethrough.

With the foregoing configuration, the workpiece transfer unit 30 according to the exemplary embodiment of the present invention receives two workpieces from the buffering chamber 40 at the same time and stands by in the transfer chamber 20 as shown in FIG. 3. If the second workpiece entrances 21a and 21b of the first multi-workpiece processing chambers 10a, 10b and 10c are open, the spindle 31 rotates and arranges the position of the end effectors 35a and 35b and the second workpiece entrances 21a and 21b. Then, the transfer arm 33 is unfolded and the end effectors 35a and 35b are introduced to the plurality of internal processing spaces A and B and load the workpiece onto the plurality of workpiece supports 170 as shown in FIG. 22. Returning to FIG. 3, the workpiece transfer unit 30 rotates and faces the buffering chamber 40 and receives the workpiece from the buffering chamber 40. Then, the workpiece transfer unit 30 sequentially transfers the workpiece to the second multi-workpiece processing chamber 10b and the third multi-workpiece processing chamber 10c. Meanwhile, if the workpiece processing process is completed at the first multi-workpiece processing chamber 10a, the workpiece transfer unit 30 causes the end effectors 35a and 35b to enter the internal processing spaces A and B to unload and transfer the processed workpiece.

Here, a workpiece transfer unit 30 according to the exemplary embodiment of the present invention rotates centering on the spindle, and sequentially loads and unloads the workpiece to the plurality of multi-workpiece processing chambers 10a, 10b and 10c, but not limited thereto. Alternatively, a workpiece transfer unit for loading only and a workpiece transfer unit for unloading only may be separately provided. That is, when the workpiece transfer unit for loading only sequentially loads the workpiece to the plurality of multi-workpiece processing chambers 10a, 10b and 10c, the workpiece transfer unit for unloading only may sequentially unload the workpiece after the processing is completed.

In the workpiece transfer unit 30 according to the exemplary embodiment of the present invention, the end effector unit 36 is fixedly coupled to the transfer arm 33, but not limited thereto. Alternatively, as shown in FIG. 16, in the workpiece transfer unit 30a according to another exemplary embodiment of the present invention, the end effector unit 36a may be rotatably coupled to the transfer arm 33. That is, the end effector unit 36a is rotatably provided in the transfer arm 33 centering on the rotation shaft 34. Here, if the end effector unit 36 is fixedly coupled to the transfer arm 33 like the exemplary embodiment of the present invention, the workpiece transfer unit 30 has a single degree of freedom but includes two degrees of freedom if the end effector unit 36a is rotatably coupled to the transfer arm 33 like the transformational exemplary embodiment. Accordingly, the transfer of workpiece may be more accurately controlled.

As shown in FIG. 25, the workpiece transfer unit 30b according to another exemplary embodiment of the present invention may be plurally provided corresponding to the number of the multi-workpiece processing chambers 10a, 10b and 10c. That is, if three multi-workpiece processing chambers 10a, 10b and 10c are provided, three transfer units 37a, 37b and 37c may be provided to load/unload the workpiece with respect to the respective multi-workpiece processing chambers 10a, 10b and 10c. In this case, the workpiece transfer speed may improve rather than when the single workpiece transfer unit rotates and transfers the workpiece to three multi-workpiece processing chambers 10a, 10b and 10c.

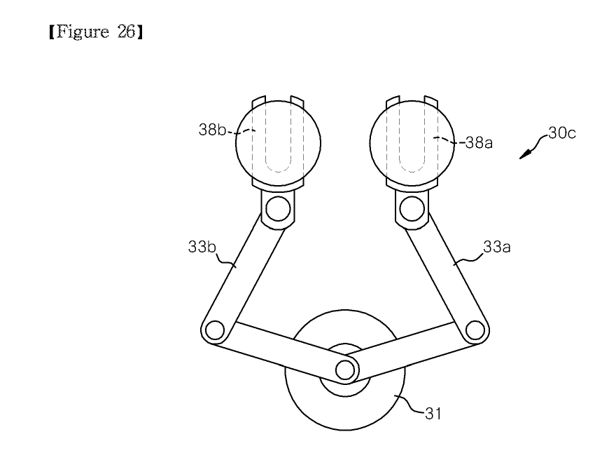

As shown in FIG. 26, a pair of transfer arms 33a and 33b of the workpiece transfer unit 30c may be rotatably provided with respect to the spindle 31. That is, each of the end effectors 38a and 38b may operate by additional transfer arms 33a and 33b. In this case, the pair of transfer arms 33a and 33b may transfer the plurality of workpieces to the multi-workpiece processing chambers 10a, 10b and 10c at the same time, or transfer the workpieces to the multi-workpiece processing chambers 10a, 10b and 10c at predetermined time intervals.

As the pair of transfer arms 33a and 33b is separately controlled in operation, only one workpiece may be transferred to the multi-workpiece processing chambers 10a, 10b and 10c. This function may be used when one of the plurality of internal processing spaces has an error and cannot process the workpiece or the workpieces in odd numbers are transferred to the buffering chamber.

That is, if the second internal processing space B of the first multi-workpiece processing chamber 10a may not process the workpiece, the workpiece is loaded to only one of the pair of end effectors 35a and 35b to be transferred to the workpiece support 170 of the first internal processing space A.

The buffering chamber 40 is changed from atmospheric pressures to vacuum or changed from vacuum to atmospheric pressures between the transfer chamber 20 and the loadlock chamber 50. The buffering chamber 40 loads the plurality of workpieces transferred by the loadlock chamber 50, and makes the workpiece transfer unit 30 load the workpiece. To support this function, the buffering chamber 40 includes a workpiece loader (not shown) to load a plurality of workpieces.

The loadlock chamber 50 receives the workpiece from the index 60 and supplies the workpiece to the workpiece loader of the buffering chamber 40. An atmospheric transfer robot (not shown) is provided in the loadlock chamber 50 to transfer the workpiece from the index 60 to the buffering chamber 40.

The index 60 is called an equipment front end module (hereinafter EFEM) or may include a loadlock chamber in some cases. The index 60 includes a cassette (load port) which is installed in a front part, and a carrier 61 which stores the plurality of workpieces is loaded on the cassette. The carrier 61 is a closed container which includes a detachable cover.

With the foregoing configuration, the workpiece processing process of the multi-workpiece processing system 1 according to the present invention will be described with reference to FIGS. 3 and 23.

First, the atmospheric transfer robot (not shown) of the loadlock chamber 50 transfers the workpiece from the carrier 61 to the buffering chamber 40. The workpiece transfer unit 30 simultaneously loads the two workpieces loaded in the buffering chamber 40 and stands by at the transfer chamber 20 as shown in FIG. 3. If the second workpiece entrances 21a and 21b are open, the workpiece which is loaded on the plurality of end effectors 35a and 35b is loaded to the plurality of workpiece support 170 of the first multi-workpiece processing chamber 10a. The workpiece transfer unit 30 receives the workpiece again from the buffering chamber 40 and sequentially transfers the workpiece to the second and the third multi-workpiece processing chambers 10b and 10c.

The multi-workpiece processing chambers 10a, 10b and 10c having the workpieces loaded on the workpiece support 170 process the workpiece by plasma generated from the plasma source unit 500. Here, as the respective processing spaces A and B have the symmetric shape by the partition member 200, the plasma is uniformly generated across the internal processing spaces, and the electric potential is also uniformly generated. Accordingly, the surface of the workpiece may uniformly be processed. After the processing, the gas is discharged to the outside by the common exhaust channel 300.

If the processing of the workpiece is completed, the second workpiece entrances 21a and 21b are open, and the workpiece transfer unit 30 unloads the workpiece from the workpiece support 170 after the processing. The unloaded workpiece is loaded to the buffering chamber 40.

Although a few exemplary embodiments of the present invention have been shown and described, it will be appreciated by those skilled in the art that changes may be made in these exemplary embodiments without departing from the principles and spirit of the invention, the scope of which is defined in the appended claims and their equivalents.

### INDUSTRIAL APPLICABILITY

As described above, a multi-workpiece processing chamber and a gas flow control method thereof according to the present invention may be efficiently used in a plasma processing process to form various layers such as a manufacture of semiconductor integrated circuits, a manufacture of flat displays and a manufacture of solar cells.

1. A multi-workpiece processing chamber comprising:
a chamber housing which forms at least two internal processing spaces therein;
at least one partition member which is provided in the chamber housing and partitions the chamber housing into at least two internal processing spaces; and
the respective internal processing spaces being coupled with the partition member and having a symmetric shape to generate a processing reaction uniformly.

2. The multi-workpiece processing chamber according to claim 1, wherein the chamber housing comprises a first curved surface which has a predetermined curvature, the partition member comprises a second curved surface which has the same curvature as that of the first curved surface, and the first curved surface and the second curved surface are coupled to each other and form a symmetric circle.

3. The multi-workpiece processing chamber according to claim 1, wherein the chamber housing comprises a plurality of housings which is coupled to each other.

4. The multi-workpiece processing chamber according to claim 3, wherein the chamber housing comprises:
an intermediate housing which has a workpiece supporting station;
an upper housing which is coupled to an upper part of the intermediate housing and forms a first curved surface; and
a lower housing which is coupled to a lower part of the intermediate housing.

5. A multi-workpiece processing system comprising:
at least one multi-workpiece processing chamber which has a plurality of internal processing spaces partitioned by a partition member;
a transfer chamber, in a circumferential area of which is disposed at least one multi-workpiece processing chamber; and
a workpiece transfer unit which is provided in the transfer chamber and transfers a workpiece to the internal processing spaces of the multi-workpiece processing chamber.

6. The multi-workpiece processing system according to claim 5, wherein the internal processing space is coupled with the partition member and has a symmetric shape to generate a uniform reaction.

7. The multi-workpiece processing system according to claim 5, wherein the transfer chamber comprises a polygonal shape, and the multi-workpiece processing chamber is provided in each side of the transfer chamber.

8. The multi-workpiece processing system according to claim 7, wherein the workpiece transfer unit comprises:
a spindle which is rotatably provided, a transfer arm which is coupled to the spindle and is foldable to move between a standby position and a transfer position loading the workpiece to the multi-workpiece processing chamber; and
an end effector unit which is coupled to an end part of the transfer arm and comprises a plurality of end effectors which is respectively provided in a plurality of internal processing spaces of the multi-workpiece processing chamber from the transfer position.

9. The multi-workpiece processing system according to claim 8, wherein the transfer arm is provided to move the end effector unit from the standby position to the central part of the transfer chamber.

10. The multi-workpiece processing system according to claim 9, wherein the end effector unit is rotatably coupled to the transfer arm.

11. The multi-workpiece processing system according to claim 10, wherein the workpiece transfer unit comprises a workpiece transfer unit for loading only which loads the workpiece to the multi workpiece processing chamber and a workpiece transfer unit for unloading only which unloads the workpiece from the multi-workpiece processing chamber.

12. A multi-workpiece processing chamber comprising:
a plurality of internal processing spaces which comprises a workpiece support;
a first gas supply ratio controller which controls a supply ratio of a gas supplied from a gas supply source to the plurality of internal processing spaces; and
a second gas supply ratio controller which is provided between the first gas supply ratio controller and the respective internal processing spaces and divides the gas supplied to the internal processing spaces and supplies gas to at least two divided parts of the internal processing spaces.

13. The multi-workpiece processing chamber according to claim 12, wherein the second gas supply ratio controller divides and supplies a gas to a central part and a circumferential part of the internal processing spaces.

14. The multi-workpiece processing chamber according to claim 13, wherein the second gas supply ratio controller controls a gas supply ratio so that the amount of gas supplied to the central part and the circumferential part differs.

15. The multi-workpiece processing chamber according to claim 12, further comprising:
a common exhaust channel through which a gas is exhausted from the plurality of internal processing spaces; and
a bypass controller which is provided between the first gas supply ratio controller and the second gas supply ratio controller and bypasses a path of the gas supplied to the internal processing spaces to the common exhaust channel.

16. The multi-workpiece processing chamber according to claim 15, wherein the bypass controller comprises:
a first opening/closing valve which is provided between the first gas supply ratio controller and the second gas supply ratio controller and controls whether to supply a gas to the internal processing spaces; and
a second opening/closing valve which is provided between the first gas supply ratio controller and the common exhaust channel and controls whether to supply a gas to the common exhaust channel.
